(19) United States
(12) Patent Application Publication
(10) Pub. No.: US 2006/0234455 A1
(43) Pub. Date: Oct. 19, 2006

(54) Structures and methods for forming a locally strained transistor

(76) Inventors: Chien-Hao Chen, Chuangwei Township (TW); Tze-Liang Lee, Hsinchu (TW)

Correspondence Address: SLATER & MATSIL, L.L.P., 17950 PRESTON ROAD, SUITE 1000, DALLAS, TX, 75252, US

(21) Appl. No.: 11/109,279

(22) Filed: Apr. 19, 2005

(51) Int. Cl. H01L 21/00

(52) U.S. Cl. 438/276

(57) ABSTRACT

Embodiments of the invention provide structures and methods for forming a strained MOS transistor. A preferred embodiment includes creating a compressive strain in a PMOS transistor for improving carrier mobility without the need for source/drain recess formation and SiGe epitaxy. Embodiments comprise forming a gate electrode on a silicon substrate, and forming a lightly doped source/drain (LDS/LDD) region in the substrate by simultaneously implanting germanium and boron in the substrate using the gate electrode as a mask. Embodiments further comprise forming spacers on opposite sidewalls of the gate electrode and forming a heavily doped source/drain region in the substrate by simultaneously implanting germanium and boron using the gate electrode and the spacers as a mask. Embodiments may further include annealing the semiconductor device to recrystallize SiGe.

### TECHNICAL FIELD

This invention relates generally to semiconductors devices, and, more particularly, to methods and structures for introducing stress into metal oxide semiconductor (MOS) devices in order to improve charge carrier mobility.

### BACKGROUND

Size reduction of metal-oxide-semiconductor field-effect transistors (MOSFETs) has enabled the continued improvement in speed performance, density, and cost per unit function of integrated circuits. One way to improve transistor performance is through selective application of stress to the transistor channel region. Stress distorts (i.e., strains) the semiconductor crystal lattice, and the distortion, in turn, affects the band alignment and charge transport properties of the semiconductor. By controlling the magnitude and distribution of stress in a finished device, manufacturers can increase carrier mobility and improve device performance. There are several existing approaches of introducing stress in the transistor channel region.

In one approach, stress in the channel is introduced after the transistor is formed. In this approach, a high-stress film, such as silicon nitride, is formed over a completed transistor. In this case, the stressor, i.e., the film, is placed above the completed transistor structure. Frequently, the stressor is a tensile layer, which because of the geometry of the structure, induces a uni-axial tensile stress in the channel.

Another approach includes forming an epitaxial, strained silicon layer on a relaxed silicon germanium (SiGe) layer. Since the SiGe lattice is larger than Si, the SiGe layer stretches the epi-layer the lateral direction, i.e., the silicon will be under a biaxial tensile stress. Another approach includes growing an epitaxial layer of SiGe within recesses in the source/drain region. In this case, lattice mismatch creates a uni-axial compressive stress within the channel region.

Still another approach includes forming an embedded stressor in the transistor source/drain region. This process includes forming a recess in the source and drain regions and then filling the recess with a second material, a stressor, having a lattice constant different from the first semiconductor material. For example, the first semiconductor material may be silicon and the second material may be SiGe. In this configuration, the larger SiGe lattice spacing induces a compressive stress within the Si channel region. Alternatively, the source and drain recesses may be filled with a second material having a smaller lattice constant, such as silicon carbide (SiC), thereby inducing tensile strain in the channel region.

One problem facing CMOS manufacturing is that NMOS and PMOS devices require different types of stress in order to achieve increased carrier mobility. For example, a biaxial, tensile stress from a silicon nitride film significantly increases NMOS performance, while a uni-axial, compressive channel strain improves PMOS performance. For this reason, the embedded SiGe stressor structure is well suited for PMOS fabrication. However, there are many challenges in this process.

Many problems relate to recess formation and subsequently epitaxial growth of th embedded stressor. One problem includes controlling the recess depth. Another problem includes maintaining the silicon surface quality during recess formation. The quality of the epitaxially grown SiGe stressor is highly dependent upon Si surface quality. Problems with recess depth and surface damage significantly affect the device short channel effects and leakage characteristics. Furthermore, the Si recess and epitaxial process have a high pattern dependence thereby making it difficult to achieve uniform control over recess depth and stressor thickness with different patterns.

In light of problems such as these, there remains a need for improved methods and structures with respect to embedded transistor stressors.

### SUMMARY OF THE INVENTION

These and other problems are generally reduced, solved or circumvented, and technical advantages are generally achieved, by embodiments of the present invention, which provides methods and structures for forming strained MOSFET and CMOS devices.

An embodiment of the invention provides a method of forming a MOS transistor, preferably a PMOS transistor. The method includes forming a gate electrode over a substrate, the substrate comprising a semiconductor crystal, wherein an interatomic distance between neighboring atoms in the semiconductor crystal is defined by a substrate lattice spacing. Embodiments further include adjusting the substrate lattice spacing under the gate electrode. In an embodiment the adjusting comprises implanting a first stressor in the substrate using the gate electrode as a mask, forming spacers on opposite sidewalls of the gate electrode, and implanting a second stressor in the substrate using the gate electrode and the spacers as a mask. In preferred embodiments, adjusting the substrate lattice spacing creates a tensile stress, and, more preferably, a tensile strain under the gate electrode. Preferably, the substrate lattice spacing under the gate electrode is adjusted at least 0.10%.

Other embodiments of the invention provide a method of forming a semiconductor device. Embodiments comprise forming a gate electrode on a substrate, and forming a lightly doped source/drain (LDS/LDD) region in the substrate by an ion implantation using the gate electrode as a mask, wherein the ion implantation includes a stressor and one of an N-type and a P-type dopant. Embodiments preferably include forming a heavily doped source/drain region in the substrate by ion implantation using the gate electrode and the gate spacers as a mask. In preferred embodiments, the ion implantation includes the stressor and one of an N-type and a P-type dopant. Embodiments further comprise annealing the semiconductor device to react the stressor and the substrate, wherein a reaction product of the stressor and the substrate has a lattice spacing different from a substrate lattice spacing. In an embodiment, the reaction product comprises SiGe. Preferably, reacting the stressor and the substrate is an alloying reaction, a solid phase transformation, crystallization or recrystallization, a chemical reaction, or a combination thereof.

Preferably, the substrate comprises a material selected from the group consisting essentially of silicon, germanium, silicon germanium, silicon on insulator (SOI), silicon germanium on insulator (SGOI), and combinations thereof. In other preferred embodiments, the stressor comprises a material such as germanium, carbon, silicon, silicon germanium, a carbide, a nitride, or combinations thereof.

A preferred embodiment includes creating a compressive strain in a PMOS transistor for improving carrier mobility without the need for source/drain recess formation and SiGe epitaxy. Embodiments comprise forming a gate electrode on a substrate, and forming a lightly doped source/drain (LDS/LDD) region in the substrate by simultaneously implanting germanium and boron in the substrate using the gate electrode as a mask. Embodiments further comprise forming spacers on opposite sidewalls of the gate electrode and forming a heavily doped source/drain region in the substrate by simultaneously implanting germanium and boron using the gate electrode and the spacers as a mask. Embodiments may further include annealing the substrate to crystallize SiGe.

In an embodiment, forming a LDS/LDD region comprises implanting boron at an energy between about 0.1 and 10 KeV, at a dose between about 1E14 and 1E16 atoms/cm², and implanting germanium at an energy between about 1 and 100 KeV, at a dose between about 1 E15 and 1E19 atoms/cm². In an embodiment, forming the heavily doped source/drain region comprises implanting boron at an energy between about 0.1 and 100 KeV, at a dose between about 1E15 to 1E17 atoms/cm², and implanting germanium at an energy between about 1 and 100 KeV, at a dose between about 1E15 to 1E19 atoms/cm². Dopant implants may further comprise co-implanting carbon, nitrogen, fluorine, or combinations thereof.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a cross-sectional view of an intermediate stage in the manufacture of a CMOS device according to embodiments of the invention;

FIG. 2 is a cross-sectional view of an embodiment comprising a simultaneous LDS/LDD dopant and stressor implant;

FIG. 3 is a cross-sectional view of an embodiment illustrating spacer formation;

FIG. 4 is a cross-sectional view of an embodiment comprising a simultaneous source/drain dopant and stressor implant; and

FIG. 5 is a cross-sectional view of the embodiment of FIG. 4 after further NMOS stressor formation according to an embodiment.

Corresponding numerals and symbols in the different figures generally refer to corresponding parts unless otherwise indicated. The figures are drawn to clearly illustrate the relevant aspects of the preferred embodiments and are not necessarily drawn to scale. To more clearly illustrate certain embodiments, a letter or symbol indicating variations of the same structure, material, or process step may follow a figure number.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention. The intermediated stages of manufacturing a preferred embodiment of the present invention are illustrated throughout the various views and illustrative embodiments of the present invention.

This invention relates generally to semiconductor device fabrication and more particularly to structures and methods for strained transistors. This invention will now be described with respect to preferred embodiments in a specific context, namely the creation of MOS and CMOS devices. Embodiments of this invention are believed to be particularly advantageous when used in this process. It is also believed that embodiments described herein will benefit other applications not specifically mentioned. Therefore, the specific embodiments discussed are merely illustrative of specific ways to make and use the invention, and do not limit the scope of the invention.

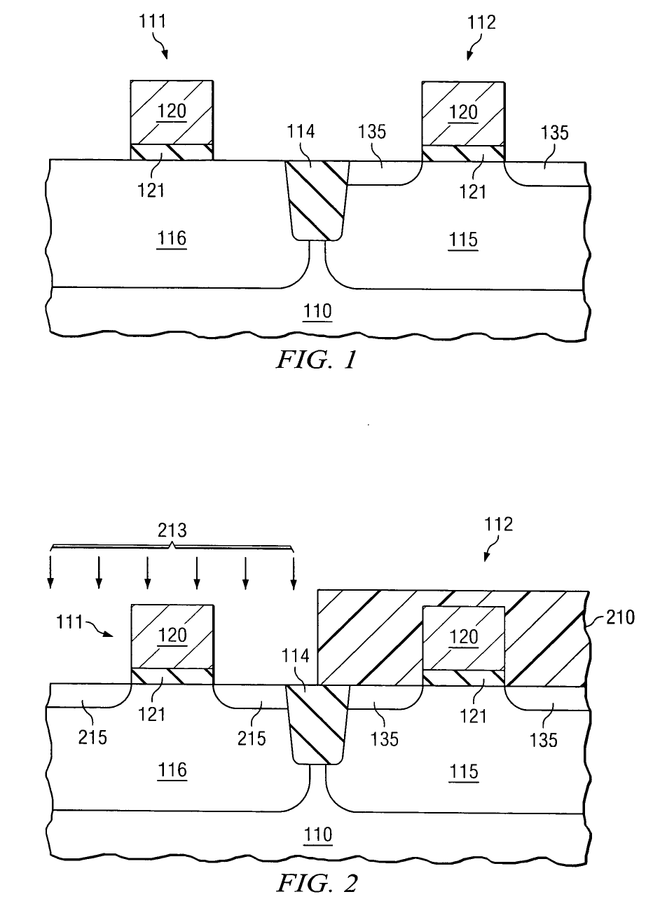

An embodiment of the invention providing a method of forming a complimentary metal oxide semiconductor (CMOS) device will now be described. In FIG. 1, there is schematically shown a semiconductor substrate 110. The substrate 110 may comprise bulk silicon, doped or undoped, or an active layer of a silicon on insulator (SOI) substrate. Generally, an SOI substrate comprises a layer of a semiconductor material such as silicon, germanium, silicon germanium, silicon on insulator (SOI), silicon germanium on insulator (SGOI), or combinations thereof. The insulator layer may be, for example, a buried oxide (BOX) layer or a silicon oxide layer. The insulator layer is provided on a substrate, typically a silicon or glass substrate. Other substrates that may be used include multi-layered substrates, gradient substrates, or hybrid orientation substrates. In the preferred embodiment illustrated in FIG. 1, the substrate 110 is comprised of single crystalline P type silicon, featuring a <100> crystallographic orientation.

In alternative embodiments, the channel/substrate orientation may be selected with a view towards optimizing the appropriate charge carrier mobility using SOI or SGOI hybrid orientation substrates. For example, an NMOS channel may be oriented along the <100> direction, which is the direction of maximum electron mobility for a {100} substrate. Alternatively, a PMOS channel may be oriented along the <110> direction, which is the direction where hole mobility is maximum for a {110} substrate.

Continuing with FIG. 1, a first region 111 of semiconductor substrate 110 will be used for accommodation of P channel metal oxide semiconductor (PMOS) devices, while second region 112 will be used for accommodation of N channel metal oxide semiconductor (NMOS) devices. An insulator filled shallow trench isolation (STI) region 114 is formed in an upper portion of the substrate 110. The STI region 114 is formed using photolithographic and dry etching procedures, followed by filling of the shallow trench shape with a silicon oxide layer using low pressure chemical vapor deposition (LPCVD) or plasma enhanced chemical vapor deposition (PECVD) and using tetraethylorthosilicate (TEOS) as a source. Removal of portions of the silicon oxide layer from the top surface of semiconductor substrate 110 is selectively accomplished via chemical mechanical polishing (CMP) procedures. A photoresist shape (not shown in the drawings) is used to block out PMOS region 111 from a procedure used to form P well region 115 in NMOS region 112. This is accomplished via implantation of boron, or BF₂ ions, at an energy between about 150 to 250 KeV, at a dose between about 1E13 to 1E14 atoms/cm². After removal of the photoresist shape used to protect PMOS region 111, from P well implantation procedures, another photoresist shape (not shown in the drawings) is used to protect NMOS region 112 from implantation of arsenic or phosphorous ions, implanted at an energy between about 300 to 600 KeV and at a dose between about 1E13 to 1E14 atoms/cm², allowing formation of N well region 116 in PMOS region 111. After removal of the photoresist 210, an anneal is performed at a temperature between about 700 to 1000° C., preferably to activate the implanted ions in both well regions.

Continuing with FIG. 1, there is further illustrated a gate electrode 120 formed on an underlying gate dielectric 121, which may be patterned by photolithography techniques as are known in the art. In an embodiment of the invention, the gate electrode 120 is comprised of poly-crystalline silicon and the gate dielectric 121 is comprised of an oxide. The patterning and etching process may be a wet or dry, anisotropic or isotropic, etch process, but preferably is an anisotropic dry etch process.

The gate dielectric 121 may include silicon oxide having a thickness from about 6 to 100 Å, and more preferably less than about 20 Å. In other embodiments, the gate dielectric 121 may include a high-k dielectric having a k-value greater than about 4. Possible high-k dielectrics include Ta₂O₅, TiO₂, Al₂O₃, ZrO₂, HfO₂, Y₂O₃, L₂O₃, and their aluminates and silicates. Other suitable high-k gate dielectrics may include a hafnium-based materials such HfO₂, HfSiOₓ, or HfAlOₓ. In a preferred embodiment in which the gate dielectric 121 comprises an oxide layer, the gate dielectric 121 may be formed by an oxidation process, such as wet or dry thermal oxidation in an ambient comprising an oxide, H₂O, NO, or a combination thereof, or by chemical vapor deposition (CVD) techniques using is tetraethylorthosilicate (TEOS) and oxygen as a precursor.

The gate electrode 120 preferably comprises a conductive material such as Ta, Ti, Mo, W, Pt, Al, Hf, Ru, and silicides or nitrides thereof, doped poly-crystalline silicon, other conductive materials, or a combination thereof. In one example, amorphous silicon is deposited and recrystallized to create poly-crystalline silicon (poly-silicon). In the preferred embodiment in which the gate electrode 120 is poly-silicon, the gate electrode 120 may be formed by depositing doped or undoped poly-silicon by low-pressure chemical vapor deposition (LPCVD) to a thickness in the range of about 400 Å to about 2500 Å, but more preferably about 1500 Å.

Embodiments may further include forming a suitable lightly doped source/drain region 135 in the NMOS region 112 according to conventional methods known in art. For example, embodiments may further include masking the PMOS region 111 and then performing an ion implant to form a lightly N doped NMOS source/drain extension (SDE) region 135 self-aligned with the gate electrode 120. A suitable implant may include a dose of phosphorus or arsenic dopant ions from about 1E13 ions/cm² to about 5E14 ions/cm² at an energy from about 30 KeV to about 80 KeV.

Turning now to FIG. 2, there is illustrated the intermediate CMOS device of FIG. 1 after further processing according to a preferred embodiment on the invention. Shown in FIG. 2, is a photoresist mask 210 formed to protect the NMOS region 112 from a LDS/LDD implant 213 used to create a lightly doped source/drain (LDS/LDD) region 215.

In preferred embodiments of the invention, the LDS/LDD implant 213 includes implanting a LDD dopant and an LDS/LDD stressor in the LDS/LDD region 215 at room temperature. The dopant and the stressor may be implanted simultaneously or sequentially in any order. Preferably, the stressor includes a material that alloys with the substrate, wherein the alloy has a lattice spacing different from the lattice spacing of the substrate. When the alloy lattice spacing is less than the substrate, it creates a tensile channel strain. When the alloy lattice spacing is greater than the substrate, it creates a compressive channel strain. Suitable stressors include germanium, carbon, silicon, silicon germanium, a carbide, a nitride, and combinations thereof.

In preferred embodiments, an upper portion of the PMOS region 111 on opposite sides of the gate electrode 120 (i.e., LDS/LDD region 215) is implanted with boron or BF₂ ions. The dopant implant may further comprise some co-implanted dopants such as carbon, nitrogen, or fluorine. It is performed at an energy between about 0.1 and 10 KeV, at a dose between about 1E14 and 1E16 atoms/cm², and at an angle between 0 and 50 degrees.

In preferred embodiments, the LDS/LDD implant 213 further includes a simultaneous stressor implant. The stressor implant includes implanting a high concentration Ge implant. The stressor implant is performed at an energy between about 1 and 100 KeV, at a dose between about 1E15 to 1E19 atoms/cm², and an angle between about 0 and 50 degrees.

The LDS/LDD implant 213 advantageously provides high concentrations of Ge doping for localized strain creation without the complicated process of recess formation and epi-layer growth of conventional PMOS stressor methods. In addition, since the implant 213 is at room temperature, it may use photoresist masks instead of complicated SiN/Oₓ hard mask formation and patterning steps. Furthermore, embodiments advantageously produce an ultra shallow junction with much better source/drain junction depth (Xⱼ) control and much better total parasitic series resistance (R_{S}) control.

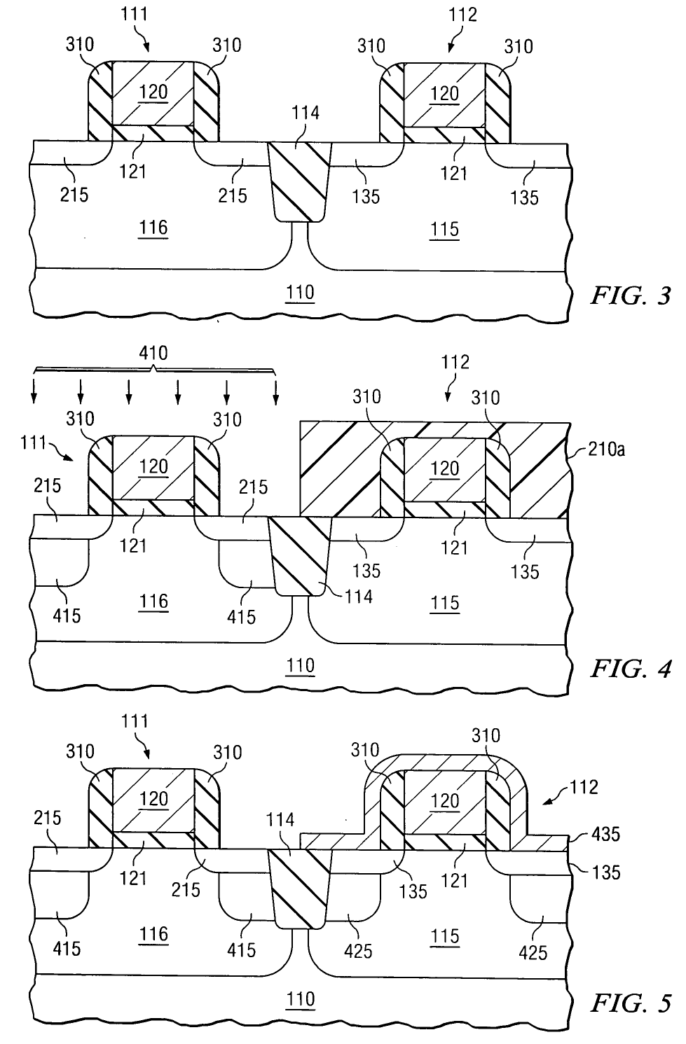

Turning now to FIG. 3, there is illustrated the intermediate device of FIG. 2 after further processing according to embodiments of the invention. The photoresist mask 210 of FIG. 2 is removed using a conventional oxygen plasma ashing. After photoresist removal, a pair of sidewall spacers 310 have been formed on opposite sides of the gate electrode 120 and gate dielectric 121. The sidewall spacers 310, serve as self aligning masks for performing one or more high concentration ion implants within the source/drain regions. The sidewall spacers 310 preferably comprise silicon nitride (Si₃N₄), or a nitrogen containing layer other than Si₃N₄, such as SiₓN_{y}, silicon oxynitride SiOₓN_{y}, silicon oxime SiOₓN_{y}:H_{z}, or a combination thereof. In a preferred embodiment, the sidewall spacers 310 are formed from a layer comprising Si₃N₄ that has been formed using chemical vapor deposition (CVD) techniques using silane and ammonia as precursor gases.

The sidewall spacers 310 may be patterned by performing an isotropic or anisotropic etch process, such as an isotropic etch process using a solution of phosphoric acid (H₃PO₄). Because the thickness of the layer of Si₃N₄ is greater in the regions adjacent to the gate electrode 120, the isotropic etch removes the Si₃N₄ material on top of the gate electrode 120 and the areas of substrate 110 not immediately adjacent to the gate electrode 120, leaving the sidewall spacers 310 as illustrated in FIG. 3. In an embodiment, the sidewall spacers 310 are from about 1 nm to about 100 nm in width.

After sidewall spacer formation, the NMOS region 112 is again protected with photoresist mask 210a as illustrated in FIG. 4. After the masking step, there is performed a source/drain implant 410. In preferred embodiments, the source/drain implant 410 may include the same processing conditions described with respect to the LDS/LDD implantation illustrated in FIG. 2. More specifically, preferred embodiments of the invention include implanting a source/drain dopant and source/drain stressor in a source/drain region 415 at room temperature. In preferred embodiments, the source/drain region 415 is implanted with boron or ⁺BF₂ ions, or further comprising some co-implanted dopants, such as carbon, nitrogen, or fluorine. The dopant implant is performed at an energy between about 0.1 and 100 KeV, at a dose between about 1E15 and 1E17 atoms/cm², and at an angle between 0 to 50 degrees. In preferred embodiments, the source/drain implant 410 further includes a stressor implant. The stressor implant includes implanting a high concentration Ge implant. The stressor implant is performed at an energy between about 1 to 100 KeV, at a dose between about 1E15 to 1E19 atoms/cm², and at an angle between 0 to 50 degrees.

Turning now to FIG. 5, there is the device of FIG. 4, after removal of the photoresist mask 210a using conventional plasma oxygen ashing procedures. Embodiments of the invention include an anneal at about 400 to 1000° C., for about 0.1 to 10 hr to activate the implanted ions. In preferred embodiments, the anneal temperature is between about 500 to 800° C. for about 0.5 to 5 hours. The anneal may be performed using either conventional furnace, or rapid thermal anneal procedures. In addition the ion activating anneal procedure can be performed using a 900 to 1100° C. spike anneal. Alternatively, the anneal may comprise a diffusion-less flash or a diffusion-less laser anneal at about 1100 to 1400° C.

In other embodiments, the anneal may be performed to adjust the properties of the stressor/substrate alloy. For example, annealing may crystallize or recrystallize the SiGe stressor. Annealing may cause other reactions within the stressor or between the stressor and substrate to improve stress-inducing properties. For example, the reaction may cause a solid phase transformation or other lattice rearrangement process, wherein the quality of the stressor/substrate interface is improved.

In other embodiments, such as in forming a semiconductor device like a MOS transistor, a stressor/substrate alloying reaction may occur during the implanting process. For example, as described above, embodiments may include implanting a first stressor in the substrate using the gate electrode as a mask, and implanting a second stressor in the substrate using the gate electrode and the spacers as a mask. Implanting the first stressor may further comprise alloying the first stressor and the semiconductor crystal to form a first alloy. Implanting the second stressor may further comprise alloying the second stressor and the semiconductor crystal to form a second alloy. Preferably, the first alloy is formed within a lightly doped source/drain region of the substrate, and the second alloy is formed within a heavily doped source/drain region of the substrate. The first and second alloys preferably have a lattice spacing different than the substrate lattice spacing. The stressor implants may further include one of an N-type and a P-type dopant.

Embodiments of the invention provided herein are particularly advantageous for forming PMOS transistors. Preferred embodiments provide structures and methods for creating a compressive strain in a PMOS transistor without the source/drain recess formation and SiGe epitaxy of conventional methods. A preferred method includes forming a gate electrode over a substrate, the substrate comprising a semiconductor crystal, wherein an interatomic distance between neighboring atoms in the semiconductor crystal is defined by substrate lattice spacing. Embodiments further include adjusting the substrate lattice spacing under the gate electrode. In an embodiment the adjusting comprises implanting a first stressor in the substrate using the gate electrode as a mask, forming spacers on opposite sidewalls of the gate electrode, and implanting a second stressor in the substrate using the gate electrode and the spacers as a mask. In preferred embodiments, adjusting the substrate lattice spacing creates a tensile stress, and, more preferably, a tensile strain under the gate electrode. Preferably, the substrate lattice spacing under the gate electrode is adjusted at least 0.10%.

For a silicon substrate, the substrate lattice spacing is about 5.4 Å (5.4295 Å) at about 25° C. In preferred embodiments, the strain under the gate electrode, i.e., the carrier channel, is preferably at least about 0.1%. In the case of silicon, a 0.1% strain corresponds to lattice displacement of about 0.0054 Å.

Before performing the activation anneal, embodiments may include a deep N+ source/drain implant that is self-aligned with the gate electrode 120 and sidewall spacers 310 to form N+ source/drain region 425. The N+ implant may comprise a dose of phosphorus or arsenic dopant from about 1E14 ions/cm² to about 1E16 ions/cm² at energy from about 10 KeV to about 80 KeV.

As illustrated in FIG. 5, the heavily doped source/drain region of the NMOS and PMOS devices are located adjacent and below their respective SDE region. In embodiments of the invention, N-type and P-type dopants independently comprise a material selected from the group consisting essentially of arsenic, phosphorous, boron, BF₂, and combinations thereof. A dopant implant may further comprise co-implanting carbon, nitrogen, or fluorine, for example.

In alternative embodiments, the stress-inducing structures and methods described above may be combined with other stress/strain techniques. For example, a tensile film is known to induce a tensile channel stress, which improves NMOS carrier mobility. Therefore, as illustrated in FIG. 5, a tensile layer 435 may be formed on the NMOS region 112.

Suitable tensile stress layers include silicon nitride, tetraethylorthosilicate (TEOS), silicon oxynitride (SiON), oxide, Si-rich nitride, or a N-rich nitride. The tensile layer 435 may have a thickness from about 200 to 1000 Å, and preferably from about 250 to 500 Å. It may be deposited by rapid thermal chemical vapor deposition (RTCVD). The RTCVD conditions include a temperature about 350 to 800° C., with a NH3:SiH4 gas ratio of about 50:1 to 400:1.

Following the embodiments of the invention described above, the CMOS device is completed using conventional semiconductor processing steps as are known in the art. A silicide may be formed by depositing a metal such as titanium or cobalt and then treated to form self-aligned silicide, or salicide, on top of the gate electrode and the source/drain region and other areas to provide a lower resistance and improve device performance. Following the salicide step interlevel insulation layers are formed above the substrate using deposition steps to deposit oxide, nitride or other conventional insulation layers, typically silicon dioxide is formed. Contact areas are patterned and etched into the insulators to expose the source/drain and gate electrodes, the resulting vias are filled with conductive material to provide electrical connectivity from metallization layers above the interlevel insulating layers down to the gate electrodes, the source, and the drain regions. Metallization layers of aluminum, or copper, may be formed over the interlevel insulation layers using known techniques such as an aluminum metallization process or a dual damascene copper metallization process to provide one, or several, wiring layers that may contact the vias and make electrical connections to the gate electrodes and the source and drain regions.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a MOS transistor, the method comprising:
forming a gate electrode over a substrate, the substrate comprising a semiconductor crystal, wherein an interatomic distance between neighboring atoms in the semiconductor crystal is defined by a substrate lattice spacing; and
adjusting the substrate lattice spacing under the gate electrode, the adjusting comprising,
implanting a first stressor in the substrate using the gate electrode as a mask;
forming spacers on opposite sidewalls of the gate electrode; and
implanting a second stressor in the substrate using the gate electrode and the spacers as a mask.

2. The method of claim 1, wherein the substrate lattice spacing under the gate electrode is adjusted at least 0.10%.

3. The method of claim 1, wherein the first stressor and the second stressor independently comprise a material selected from the group consisting essentially of germanium, carbon, silicon, silicon germanium, a carbide, a nitride, and combinations thereof.

4. The method of claim 1, wherein the substrate lattice spacing is about 5.4 Å at about 25° C.

5. The method of claim 1, wherein implanting the first stressor further comprises alloying the first stressor and the semiconductor crystal to form a first alloy, the first alloy being formed within a lightly doped source/drain region of the substrate, wherein the first alloy has a lattice spacing different than the substrate lattice spacing.

6. The method of claim 1, wherein implanting the second stressor further comprises alloying the second stressor and the semiconductor crystal to form a second alloy, the second alloy being formed within a heavily doped source/drain region of the substrate, wherein the second alloy has a lattice spacing different than the substrate lattice spacing.

7. The method of claim 1, wherein implanting the first stressor and implanting the second stressor comprise implanting germanium at an energy between about 1 and 100 KeV, and at a dose between about 1E15 to 1E19 atoms/cm².

8. The method of claim 1, further comprising annealing the MOS transistor to recrystallize a portion of the substrate.

9. The method of claim 8, wherein annealing the MOS transistor comprises annealing at about 400 to 1000° C., for about 0.1 to 10 hr.

10. The method of claim 8, wherein annealing the MOS transistor comprises an anneal selected from the group consisting essentially of a spike anneal at about 900 to 1100° C., a laser diffusion-less anneal at a temperature between about 1000 and 1400° C., and a flash diffusion-less anneal at a temperature between about 1000 and 1400° C.

11. A method of forming a semiconductor device comprising:
forming a gate electrode on a substrate;
forming a lightly doped source/drain (LDS/LDD) region in the substrate by a first ion implantation using the gate electrode as a mask, wherein the first ion implantation includes a stressor and one of an N-type and a P-type dopant;
forming sidewall spacers on opposite sidewalls of the gate electrode;
forming a heavily doped source/drain region in the substrate by a second ion implantation using the gate electrode and the sidewall spacers as a mask, wherein the second ion implantation includes the stressor and one of the N-type and the P-type dopant; and
annealing the semiconductor device to react the stressor and the substrate, wherein a reaction product of the stressor and the substrate has a lattice spacing different from a substrate lattice spacing.

12. The method of claim 11, wherein the stressor comprises a material selected from the group consisting essentially of germanium, carbon, silicon, silicon germanium, a carbide, a nitride, and combinations thereof.

13. The method of claim 11, wherein the N-type and the P-type dopants independently comprise a material selected from the group consisting essentially of arsenic, phosphorous, boron, BF₂, and combinations thereof.

14. The method of claim 11, wherein the reaction product of the stressor and the substrate comprises SiGe.

15. The method of claim 11, wherein forming the LDS/LDD region comprises simultaneously implanting boron and germanium.

16. The method of claim 15, wherein forming the LDS/LDD region further comprises implanting boron at an energy between about 0.1 and 10 KeV, at a dose between about 1E14 and 1E16 atoms/cm², and implanting germanium at an energy between about 1 and 100 KeV, at a dose between about 1E15 and 1E19 atoms/cm².

17. The method of claim 15, further comprising co-implanting a material selected from the group consisting essentially of carbon, nitrogen, fluorine, and combinations thereof.

18. The method of claim 11, wherein forming the heavily doped source/drain region comprises simultaneously implanting boron and germanium.

19. The method of claim 18, wherein forming the heavily doped source/drain region further comprises implanting boron at an energy between about 0.1 and 100 KeV, at a dose between about 1E15 to 1E17 atoms/cm², and implanting germanium at an energy between about 1 and 100 KeV, at a dose between about 1E15 to 1E19 atoms/cm².

20. The method of claim 18, further comprising co-implanting a material selected from the group consisting essentially of carbon, nitrogen, fluorine, and combinations thereof.

21. The method of claim 11, wherein annealing the semiconductor device comprises annealing at about 500 to 1000° C. for about 0.1 to 10 hr.

22. The method of claim 11, wherein annealing the semiconductor device comprises an anneal selected from the group consisting essentially of a spike anneal at about 900 to 1100° C., a laser diffusion-less anneal at about 1000 to 1400° C., and a flash diffusion-less anneal at 1000 to 1400° C.

23. The method of claim 11, wherein the reaction product of the stressor and the substrate has a lattice spacing greater than the substrate lattice spacing.

24. A method of creating a compressive strain in a PMOS transistor for improving carrier mobility, the method comprising:
forming a gate electrode on a substrate;
forming a lightly doped source/drain (LDS/LDD) region in the substrate by simultaneously implanting germanium and boron in the substrate using the gate electrode as a mask;
forming spacers on opposite sidewalls of the gate electrode;
forming a heavily doped source/drain region in the substrate by simultaneously implanting germanium and boron using the gate electrode and the spacers as a mask; and
annealing the substrate to crystallize SiGe.

25. The method of claim 24, wherein forming a LDS/LDD region comprises implanting boron at an energy between about 0.1 and 10 KeV, at a dose between about 1E14 and 1E16 atoms/cm², and implanting germanium at an energy between about 1 and 100 KeV, at a dose between about 1E15 and 1E19 atoms/cm².

26. The method of claim 25, further comprising co-implanting a material selected from the group consisting essentially of carbon, nitrogen, fluorine, and combinations thereof

27. The method of claim 24, wherein forming the heavily doped source/drain region comprises implanting boron at an energy between about 0.1 and 100 KeV, at a dose between about 1E15 to 1E17 atoms/cm², and implanting germanium at an energy between about 1 and 100 KeV, at a dose between about 1E15 to 1E19 atoms/cm².

28. The method of claim 27, further comprising co-implanting a material selected from the group consisting essentially of carbon, nitrogen, fluorine, and combinations thereof.
